(19) United States
(12) Patent Application Publication
(10) Pub. No.: US 2013/0240951 A1
(43) Pub. Date: Sep. 19, 2013

(54) GALLIUM NITRIDE SUPERJUNCTION DEVICES

(71) Applicants: Stephen W. Bedell, Wappingers Falls, NY (US); Bahman Hekmatshoartabari, White Plains, NY (US); Devendra K. Sadana, Pleasantville, NY (US); Ghavam G. Shahidi, Pound Ridge, NY (US); Davood Shahrjerdi, White Plains, NY (US)

(72) Inventors: Stephen W. Bedell, Wappingers Falls, NY (US); Bahman Hekmatshoartabari, White Plains, NY (US); Devendra K. Sadana, Pleasantville, NY (US); Ghavam G. Shahidi, Pound Ridge, NY (US); Davood Shahrjerdi, White Plains, NY (US)

(73) Assignee: International Business Machines Corporation, Armonk, NY (US)

(21) Appl. No.: 13/418,438

(22) Filed: Mar. 13, 2012

(51) Int. Cl. H01L 29/778; H01L 29/872

(52) U.S. Cl. 257/194; 257/201; 257/E29.246; 257/E29.338

(57) ABSTRACT

Gallium nitride high electron mobility transistor structures enable high breakdown voltages and are usable for high-power, and/or high-frequency switching. Schottky diodes facilitate high voltage applications and offer fast switching. A superjunction formed by p/n junctions in gallium nitride facilitates operation of the high electron mobility transistor structures and Schottky diodes as well as gated diodes formed by drain to gate connections of the transistor structures. Breakdown between the gate and drain of the high electron mobility transistor structures, through the substrate, or both is suppressed.

### FIELD OF THE INVENTION

The present invention relates to the physical sciences and, more particularly, to high electron mobility transistor structures and Schottky diodes.

### BACKGROUND

High electron mobility transistors have been developed that generate high mobility electrons through the use of heterojunctions. Gallium nitride devices are useful for high power, high frequency switching because of the high critical breakdown electric field and high saturation velocity of carriers in gallium nitride (GaN), allowing for improved device breakdown voltages without compromising the specific on-resistance of the device. The large bandgap of gallium nitride also allows for device operation at high temperatures.

The schematic structure of a GaN high electron mobility transistor (HEMT) is shown in FIG. 1. The transistor 20 includes a layer of aluminum gallium nitride 22 adjoining a gallium nitride layer 24. A conductive channel 26 formed by 2D electron gas (2DEG) is formed between the source 28 and drain 30. The gate 32 adjoins the aluminum gallium nitride layer 22 in the illustrated transistor, though an insulator layer (not shown) may be provided beneath the gate 32 to form a metal-insulator-semiconductor (MIS) HEMT. The GaN layer is formed on a substrate 36 of, for example, silicon, silicon carbide or sapphire. A nucleation layer 38 is provided between the gallium nitride layer 24 and the substrate in the depicted transistor. The nucleation layer may be formed of a material such as gallium nitride, aluminum gallium nitride or aluminum nitride. A passivation layer 39 is provided on the structure. The passivation layer is comprised of silicon nitride in the HEMT of FIG. 1. Despite the large bandgap of gallium nitride, the breakdown voltages of GaN HEMT devices as discussed with respect to FIG. 1 are limited to 2KV due to the premature breakdown of GaN.

GaN-on-Si Schottky diodes have been developed and offer fast switching as the reverse recovery charge is negligible. Such diodes may include a Si(111) substrate, a GaN layer, a buffer layer between the substrate and GaN layer, a passivation layer overlying the GaN layer, a guard ring, and a Schottky contact.

### BRIEF SUMMARY

Principles of the invention provide a GaN high electron mobility transistor structure that allows high breakdown voltages. An exemplary high electron mobility transistor structure includes a doped gallium nitride superjunction layer comprising a plurality of p/n junctions and a barrier layer adjoining the doped gallium nitride superjunction layer. The doped gallium nitride superjunction layer is positioned between the substrate layer and the barrier layer. A two dimensional electron gas channel is formed in the doped gallium nitride superjunction layer near the junction of the doped gallium nitride superjunction layer and the barrier layer when a voltage is applied across the gate and source terminals. A passivation layer overlies the barrier layer. An electric field set up by the doped gallium nitride superjunction layer is vertical to an electric field set up between the gate electrode and the drain electrode upon application of a voltage to the gate electrode.

In accordance with another aspect, a high electron mobility transfer structure includes a doped gallium nitride superjunction layer having a thickness of less than ten microns and comprises a plurality of p/n junctions. The entirety of the thickness of the doped gallium nitride superjunction layer comprises a superjunction structure. The high electron mobility transfer structure further includes a silicon substrate layer and an aluminum gallium nitride barrier layer adjoining the doped gallium nitride superjunction layer. The doped gallium nitride superjunction layer is positioned between the substrate layer and the barrier layer A two dimensional electron gas channel is formed in the doped gallium nitride superjunction layer near the junction of the doped gallium nitride superjunction layer and the barrier layer when a voltage is applied across the gate and source terminals of the structure. The doped gallium nitride superjunction layer is operable to suppress breakdown both through the silicon substrate layer and between the gate and drain.

A Schottky diode structure is provided in accordance with another aspect. An exemplary Schottky diode includes a Schottky contact, a substrate having a top surface, and a doped gallium nitride superjunction layer between the Schottky contact and the top surface of the substrate. The doped gallium nitride superjunction layer has a thickness of less than ten microns and comprises a plurality of p/n junctions, the entirety of the thickness of the doped gallium nitride superjunction layer comprising a superjunction structure, the p/n junctions extending vertically with respect to the top surface of the substrate.

As used herein, “facilitating” an action includes performing the action, making the action easier, helping to carry the action out, or causing the action to be performed.

Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Techniques of the present invention can provide substantial beneficial technical effects. For example, one or more embodiments may provide one or more of the following advantages:
High breakdown voltages by suppression of breakdown through the substrate;
High breakdown voltages by suppression of breakdown between the gate and drain;
Allow the use of low cost Si substrates for high breakdown voltage devices.

These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 shows a schematic illustration of a prior art GaN high electron mobility transistor;

FIG. 2 shows a schematic illustration of a high electron mobility transistor structure in accordance with a first exemplary embodiment;

FIG. 3 is a flow diagram showing an exemplary process for fabricating the high electron mobility transistor structure of FIG. 2;

FIG. 4 shows a schematic illustration of a high electron mobility transistor structure in accordance with a second exemplary embodiment;

FIG. 5 shows a schematic illustration of a Schottky diode structure in accordance with a third exemplary embodiment;

FIG. 6 shows a schematic illustration of a Schottky diode structure in accordance with a fourth exemplary embodiment;

FIGS. 7A and 7B show exemplary embodiments of Schottky diode structures;

FIG. 8 shows a further exemplary embodiment of a Schottky diode structure;

FIG. 9 is a flow diagram showing an exemplary process for fabricating a structure useful for constructing a high electron mobility transfer structure or a Schottky diode structure, and

FIG. 10 is a flow diagram showing a further exemplary process for fabricating a structure useful for constructing a high electron mobility transfer structure or a Schottky diode structure.

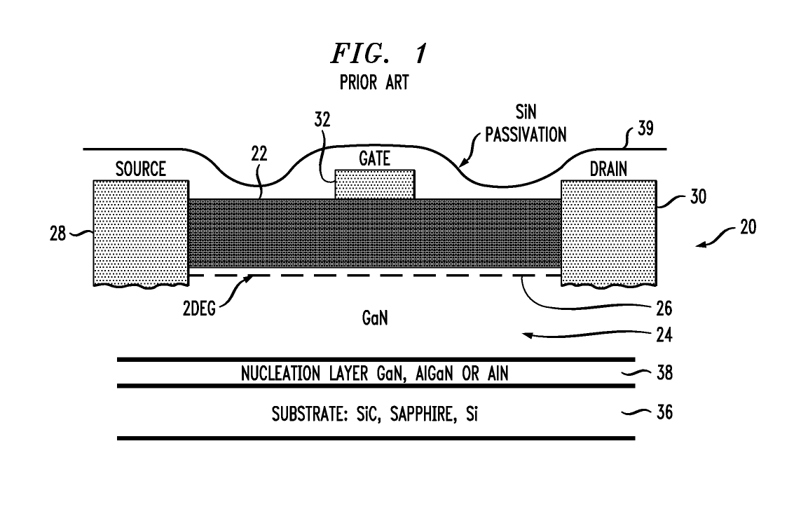

### DETAILED DESCRIPTION

High electron mobility transistors are disclosed that are characterized by high breakdown voltages. In exemplary embodiments, a gallium nitride superjunction is provided between the channel and the substrate, suppressing breakdown both through the substrate and between the gate and drain. Exemplary embodiments of Schottky diode structures including doped gallium nitride superjunction layers are also disclosed.

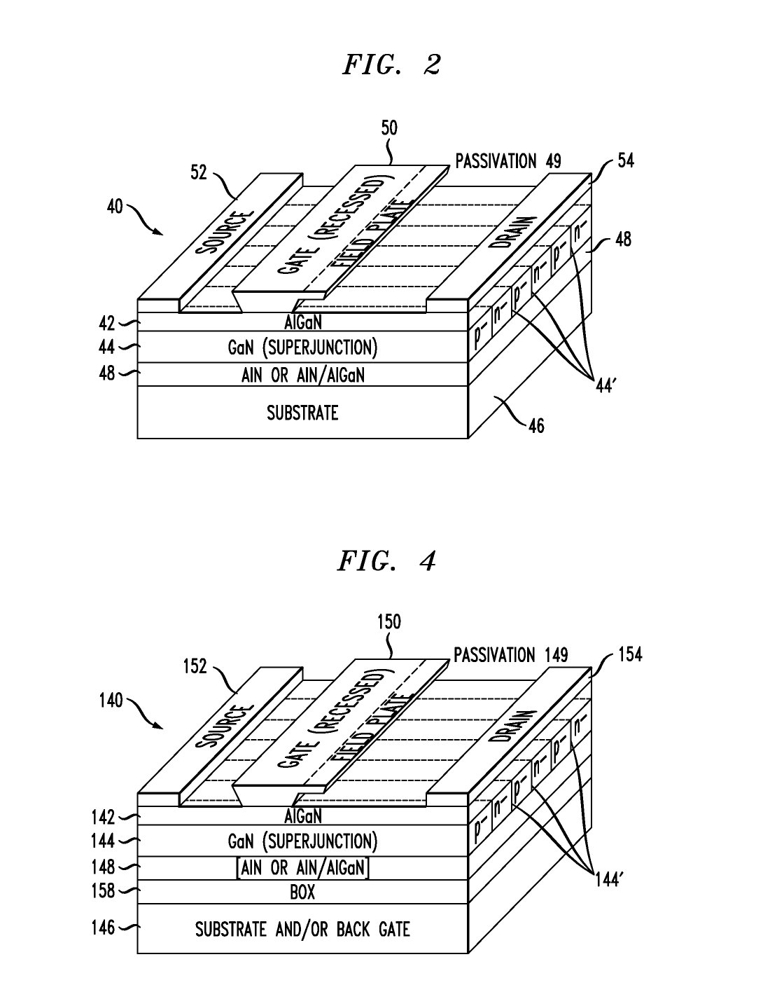

A first exemplary embodiment is shown in the schematic illustration provided in FIG. 2. The HEMT structure 40 shown in FIG. 2 includes a barrier layer of aluminum gallium nitride (AlGaN) 42 adjoining a gallium nitride superjunction layer 44 formed by p/n junctions 44′ in the GaN. More specifically, the entirety of the GaN material between the channel and the substrate 46 is a superjunction comprised of p/n junctions 44′ that extend vertically with respect to the top surface of the substrate and the bottom surface of the barrier layer. In operation, the channel is formed inside the GaN layer close to the GaN/AlGaN interface. Due to the two-dimensional quantum confinement of electrons in the channel, the channel is typically referred to as two dimensional electron gas, or 2DEG. The doped GaN p/n junctions 44′ extend vertically with respect to the channel electric field. Current flows in both the p- and n-GaN parallel to each other when voltage is applied to the gate 50, also known as the gate electrode. Channel conduction mode in the n- and p-GaN layers is accumulation and inversion, respectively. The electric field set up by the GaN superjunction is vertical to the electric field set up between the gate and the drain, and also vertical to the electric field set up between the drain and the Si(111) substrate. As known from the theory of superjunctions, the spatial distribution of an electric field vertical to that set up by the superjunction is modified in such a way that the maximum value of the vertical electric field in the GaN material is reduced. As a result, the breakdown voltage is increased accordingly. This applies to both the electric field set up between the gate and the drain and the electric field set up between the gate and the Si(111) substrate.

The gate 50 adjoins the aluminum gallium nitride barrier layer 42, though a dielectric layer (not shown) may be provided beneath the gate 50 to form a metal-insulator-semiconductor (MIS) HEMT structure. The gate may optionally be recessed to further reduce the electric field on the drain side of the gate (not shown). A field plate extends from the gate and extends over the barrier layer 42. Field-plates are widely used in high voltage devices including GaN HEMTs to reduce the electric field on the drain side of the gate, and suppress premature breakdown between the gate and the drain. Source and drain electrodes 52, 54 are also formed on the AlGaN barrier layer 42. A buffer layer 48 is formed between the substrate 46 and the GaN superjunction layer 44. The buffer layer 48 in this illustrative embodiment is formed of aluminum nitride (AlN).

It will be appreciated that both the barrier and buffer layers can be formed of materials other than those identified above. For example, the barrier layer can be comprised of any suitable material that will grow on gallium nitride and provide a large band gap. Other materials which may be used as the barrier layer include but are not limited to AlInN, AlGaInN, AlN/AlInN bilayer or superlattice. The buffer layer can be any material that has a smaller lattice mismatch with the substrate material compared to that of GaN with the substrate material, and therefore reduces the built-in strain in GaN.

The substrate 46 in this exemplary embodiment is preferably comprised of Si(111), although other substrate materials known to those of skill in the art such as silicon carbide (SiC), sapphire or zinc oxide (ZnO) could alternatively be employed. A GaN substrate could alternatively be used, eliminating the need for any additional GaN growth. Si(111) is the preferred substrate material because of its significantly lower cost and superior thermal conductivity. However, the growth of GaN on Si(111) is challenging due the lattice mismatch between GaN and Si(111), and buffer layers such as AlGaN or AlN are typically grown on Si(111) prior to GaN growth to reduce the lattice mismatch. The lattice mismatch between GaN and Si(111) results in mechanical strain in the GaN layer leading to the creation of structural defects in GaN after a critical strain level is reached. The defects degrade the electrical properties of the GaN layer such as carrier mobility and the critical electric field (and therefore the inherent breakdown voltage of GaN). The accumulation of the mechanical strain in GaN also results in the bowing of the substrate (and the layers grown on the substrate) and may lead to the cracking and delamination of the layers. Since the accumulated strain is increased as the thickness of the grown layers is increased, the thickness of the GaN channel material is typically limited to less than ten (10) microns. Therefore, the GaN-on-Si HEMT devices are particularly prone to breakdown through the Si substrate (i.e. breakdown between the drain and Si substrate, through the GaN channel material; hence, typically the thinner the GaN layer, the lower the breakdown voltage). The improvements disclosed herein are accordingly particularly relevant to GaN-on-Si devices which are most prone to breakdown though the substrate. Breakdown between gate and drain is in principle independent of the substrate type and is suppressed by employing a superjunction structure as disclosed herein, regardless of the type of the substrate material being used.

A second AlGaN layer may be provided beneath the GaN layer 44 to form a double heterojunction HEMT (DH-HEMT) in an alternative embodiment, in which case the layer 48 shown in FIG. 2 would actually comprise two layers, specifically the AlN buffer layer and the second AlGaN layer. Alternatively, an AlN/GaN supperlattice, an AlInN layer, an AlGaInN layer, or an InGaN layer may be used instead of the second AlGaN layer. A passivation layer 49 is provided on the structure 40 and overlies the barrier layer 42. The passivation layer is comprised of silicon nitride in this exemplary embodiment. The source 52 may overlap the gate, running over the passivation layer 49 to overlap the channel on the drain side of the gate 50, to form a second field plate (not shown). The presence of the GaN superjunction layer 44 in the HEMT structure shown in FIG. 2 enhances the voltage sustaining level in the GaN beyond the Poisson limit and improves the breakdown voltage of the structure 40. The superjunction serves to suppress breakdown both through the substrate and between the gate and drain.

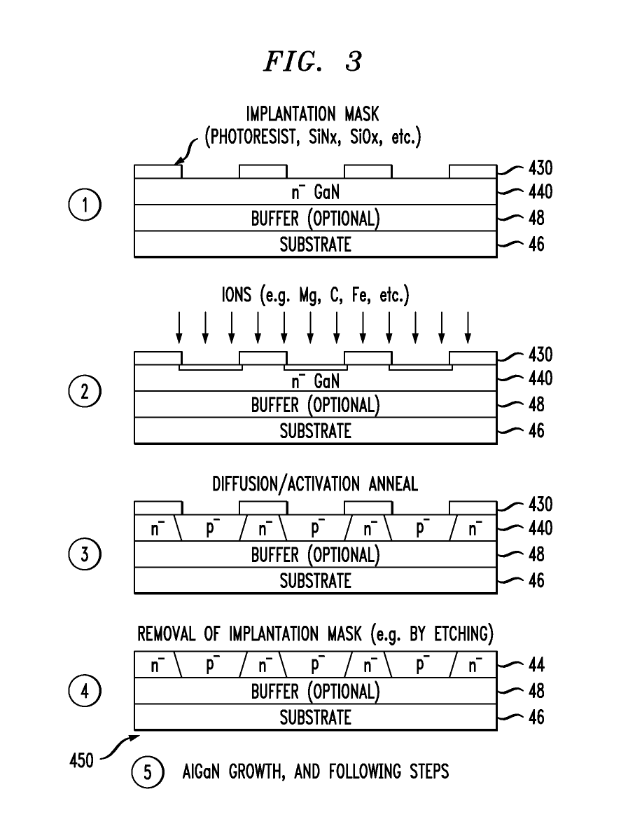

The embodiment of FIG. 2 is prepared by growing the buffer, superjunction and barrier layers on the substrate 46. Metal organic chemical vapor deposition (MOCVD), molecular beam epitaxy (MBE) and/or other techniques familiar to those of skill in the art may be employed. The superjunction can be formed by growing n-GaN, followed by masked implantation and/or diffusion to form the p-GaN layers. The n-type conductivity of GaN may arise from the presence of defects such as vacancies or Si dopant atoms in GaN. An exemplary process flow is shown in FIG. 3.

Referring to step 1 in FIG. 3, the substrate 46 has a n-GaN layer 440, the optional buffer layer 48, and an implantation mask 430 formed thereon. In step 2, ions are implanted in the n-GaN layer 440. The ions may be, for example, magnesium or zinc. In step 3, the ions are distributed within the n-GaN layer through processes known to those of skill in the art, namely diffusion and/or activation anneal in the exemplary process. Activation anneal places dopant atoms on lattice sites. Distribution of the dopant atoms is such that n-GaN regions remain in the layer 440 beneath the implantation mask. The entirety of the thickness of the GaN material is a superjunction structure following step 3. The implantation mask 430 is removed in step 4, leaving a structure 450 comprising the substrate 46, optional buffer layer 48 and GaN superjunction layer 44. It will be appreciated that the vertical p/n junctions formed in this procedure are not entirely orthogonal to the buffer layer 48 nor will they be orthogonal to the barrier layer subsequently formed thereon. Orthogonal junctions are not required. The AlGaN barrier layer 42 can thereafter be grown on the structure 450 in step 5. It will be appreciated that fabrication process as described above can be conducted on a wafer scale.

A further exemplary embodiment of a HEMT structure 140 is shown in FIG. 4. The structure shown in FIG. 4 includes a barrier layer of aluminum gallium nitride (AlGaN) 142 adjoining a doped gallium nitride superjunction layer 144 formed by p/n junctions 144′ in the GaN. As discussed above with respect to the embodiment of FIG. 2, other large band gap materials could be employed for the barrier layer. Similar to the embodiment of FIG. 2, the entirety of the GaN material between the conductive channel and the substrate 146 is a superjunction. The doped GaN p/n junctions 144′ extend vertically with respect to the channel electric field. The junctions of the n- and p-regions may be oriented as shown in FIG. 3, which is considered vertical with respect to this element. Current flows in both the p- and n-GaN parallel to each other when voltage is applied to the gate 150. The gate 150 adjoins the aluminum gallium nitride layer 142, though a dielectric layer (not shown) may be provided beneath the gate 150 to form a metal-insulator-semiconductor (MIS) HEMT structure. The gate may optionally be recessed (not shown). Source and drain electrodes 152, 154 are also formed on the AlGaN barrier layer 142. A buffer layer 148 is optionally formed between the substrate 146 and the GaN superjunction layer 144. The buffer layer 148 in this illustrative embodiment is formed of aluminum nitride (AlN). A passivation layer 149 is provided on the structure 140. The passivation layer is comprised of silicon nitride in this exemplary embodiment. The source 152 may overlap the gate, running over the passivation layer 149 to overlap the channel on the drain side of the gate 150, to form a second field plate (not shown). In the embodiment of FIG. 4, the structure is detached from the substrate and bonded to an insulating or insulator-on-semiconductor substrate such as silicon-dioxide on Si. Such a substrate may be formed by various methods known in the art, such as thermal oxidation of the Si substrate followed by removal of the oxide from one side; deposition or growth of oxide or nitride on one side of the Si substrate; or using a Si on insulator (SOI) substrate in which a top thin Si layer has been etched away. In the case of insulator on Si, the Si substrate can serve as a back gate, which may improve the electrostatics of the transistor, including the reduction of the off-current. The back gate bias may also be used for adjusting the threshold voltage of the transistor, as known in the art. This may be particularly useful in the case of DH-HEMT devices. Layer transfer may be achieved by spalling or other known techniques. U.S. Pub. No. 2010/0307572 discloses layer transfer techniques applicable to fabrication of the structure 140, and is incorporated by reference herein. The presence of the GaN superjunction layer 144 in the HEMT structure shown in FIG. 4 enhances the voltage sustaining level in the GaN beyond the Poisson limit and improves the breakdown voltage of the structure 140. The superjunction serves to suppress breakdown both through the substrate and between the gate and drain. The embodiment of FIG. 4 allows for even higher breakdown voltages due to the insulating buried oxide (BOX) layer 158 that helps prevent the permeation of the depletion region into the substrate that could otherwise result in premature breakdown through the Si substrate. This embodiment is also advantageous in that it allows thinner GaN layers to be used compared to embodiment of FIG. 2, due to the presence of the BOX layer. Growing thinner GaN layers on Si is less demanding since the accumulated strain due to lattice mismatch is increased as the thickness of the GaN layer grown on Si is increased. As in the embodiment of FIG. 2, the superjunction serves to suppress breakdown both through the substrate and between the gate and drain, not just between the gate and drain. Like the other embodiment disclosed herein, the embodiment of FIG. 4 can be formed as a double heterojunction HEMT.

The p-regions forming the superjunction in GaN may be doped by impurities such as Mg and Zn. The doping levels of the p-regions may range from 5×10¹⁵ cm³ to 5×10¹⁷ cm³ but higher or lower doping levels are also possible. The widths of the p-regions may range from 500 nm to 5 μm but thinner or wider regions are also possible. The n-regions forming the superjunction in GaN may be doped by impurities such as Si or result from the defects present in GaN. The doping levels of the n-regions may range from 10¹⁵ cm⁻³ to 5×10¹⁶ cm⁻³ but higher or lower doping levels are also possible. The widths of the n-regions may range from 500 nm to 3 μm but thinner or wider regions are also possible.

GaN superjunctions as formed in the manner disclosed in FIG. 3 can be employed to form diode structures. The gate and drain electrodes of the embodiments of FIGS. 2 and 4 can, for example, be electrically connected to function as diodes (not shown).

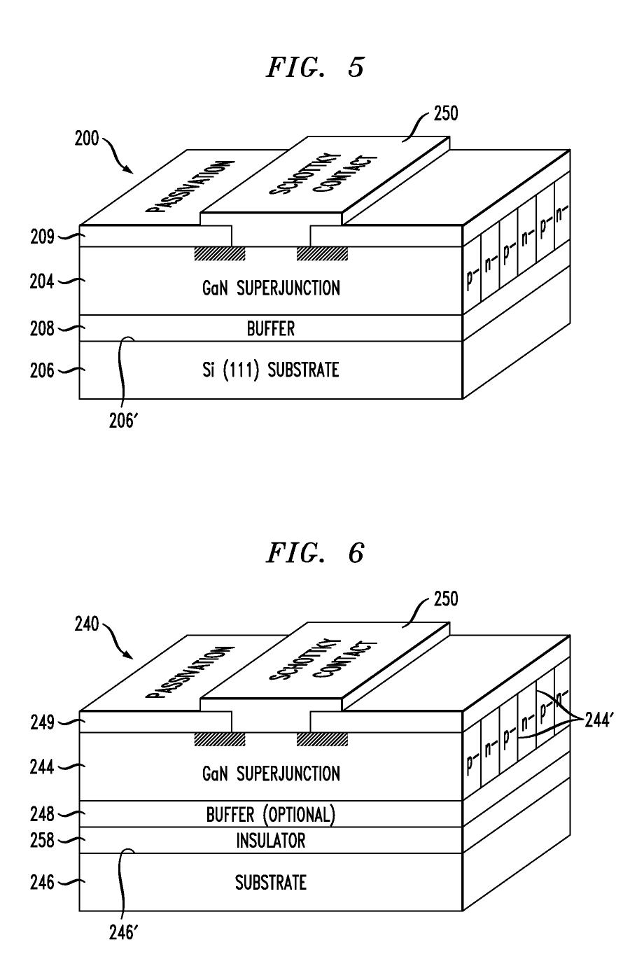

FIGS. 5 and 6 show schematic illustrations of Schottky diode structures 200, 240 including doped gallium nitride superjunction layers. Referring first to FIG. 5, the exemplary structure includes a doped gallium nitride superjunction layer 204, a Si(111) substrate layer 206, and a buffer layer 208 therebetween. The buffer layer may comprise aluminum nitride. An ion-implanted guard ring 210 is provided in the GaN layer 210 helps prevent damage to the Schottky junction. The implantation of argon may be conducted in the fabrication of the structure 200 to create a high resistivity area. Implantation of other ions such as magnesium or zinc is an alternative approach. Argon, magnesium and zinc are non-limiting examples. Those skilled in the art will appreciate that guard rings are well known features of Schottky diodes. A passivation layer 209 is formed on the GaN layer 204. A Schottky contact 250 adjoins the doped GaN superjunction layer 204, forming a Schottky barrier. The doped GaN superjunction layer 204 is similar to those employed in the HEMT structures described above with respect to FIGS. 2, 3 and 4. It is comprised of a plurality of p- and n-regions having junctions that extend vertically between the buffer layer 208 and the passivation layer 209 or Schottky contact 250. The junctions may extend orthogonally to the direction shown in FIG. 5. As discussed above with respect to FIG. 3, the junctions are unlikely to be perpendicular with respect to the top surface 206′ of the substrate layer or adjoining layers due to the manner in which they are formed. It will accordingly be appreciated that the schematic illustrations provided herein, such as FIG. 5, may not be to scale or show boundaries between elements in precise orientations. The superjunction layer 204 in this exemplary embodiment has a thickness of less than ten microns, the entire thickness comprising a superjunction structure. The substrate layer 206 in this exemplary embodiment is Si(111), though other substrate materials known to those of skill in the art may be employed.

The Schottky diode structure 240 of FIG. 6 includes substrate, insulator, doped gallium nitride superjunction and passivation layers 246, 258, 244 and 249, respectively, and an optional buffer layer 248. The doped gallium nitride superjunction layer is the same in structure as the layer 204 discussed above with respect to FIG. 5. The junctions 244′ extend vertically with respect to the top surface 246′ of the substrate and the bottom surface of the passivation layer. The insulator 258 may be a buried oxide (BOX) layer.

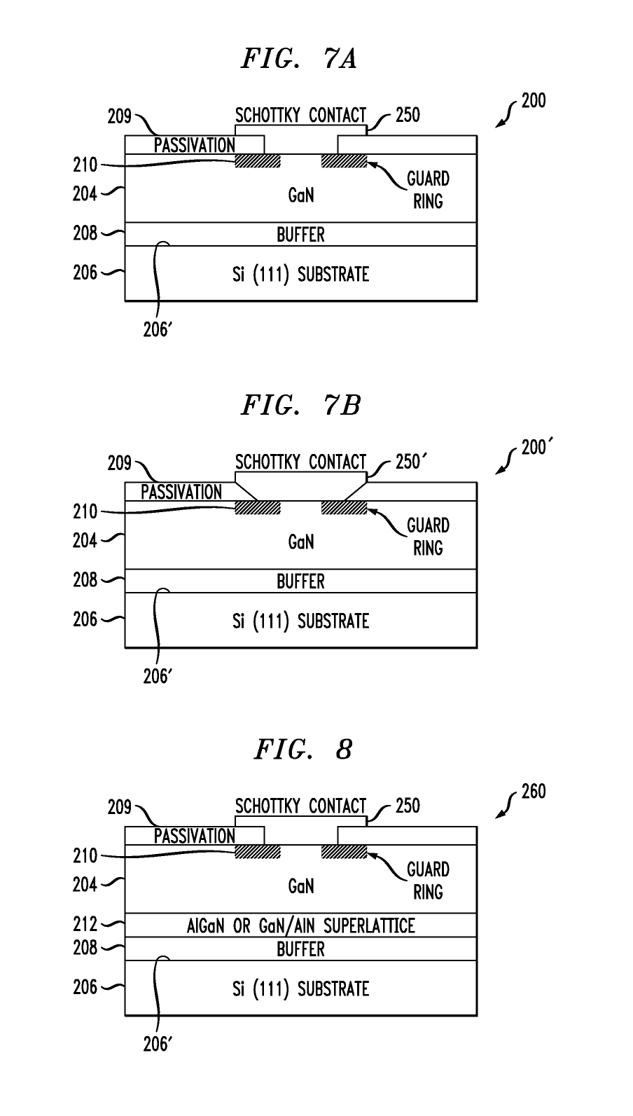

FIGS. 7A and 7B are schematic illustrations of similar Schottky diode structures. The structure 200 shown in FIG. 7A is the same structure as shown in FIG. 5 though the junctions in the doped gallium nitride superjunction layer 204 are not visible in this view. Such junctions would be visible in this view if they were formed orthogonally with respect to the directions in which the junctions in this exemplary embodiment are formed, and could resemble the vertical junctions formed in the GaN layer shown in FIG. 3. FIG. 7B shows a Schottky diode structure 200′ having the same structure as the structure 200 shown in FIG. 7A except for the configuration of the Schottky contact 250′ and adjoining passivation layer.

FIG. 8 shows a Schottky diode structure 260 having elements in common with the structures shown in FIGS. 7A and 7B, the same reference numbers being used to designate such elements. The structure 260 further includes an AlGaN layer or a GaN/AlN superlattice layer 212 between the buffer layer 208 and the doped gallium nitride superjunction layer 204.

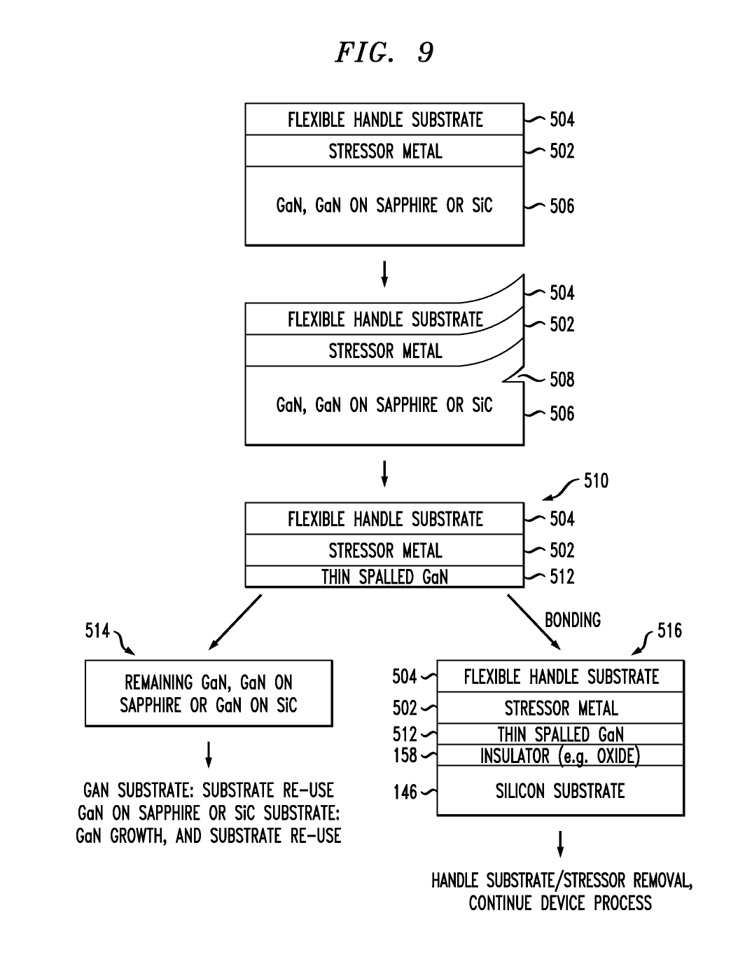

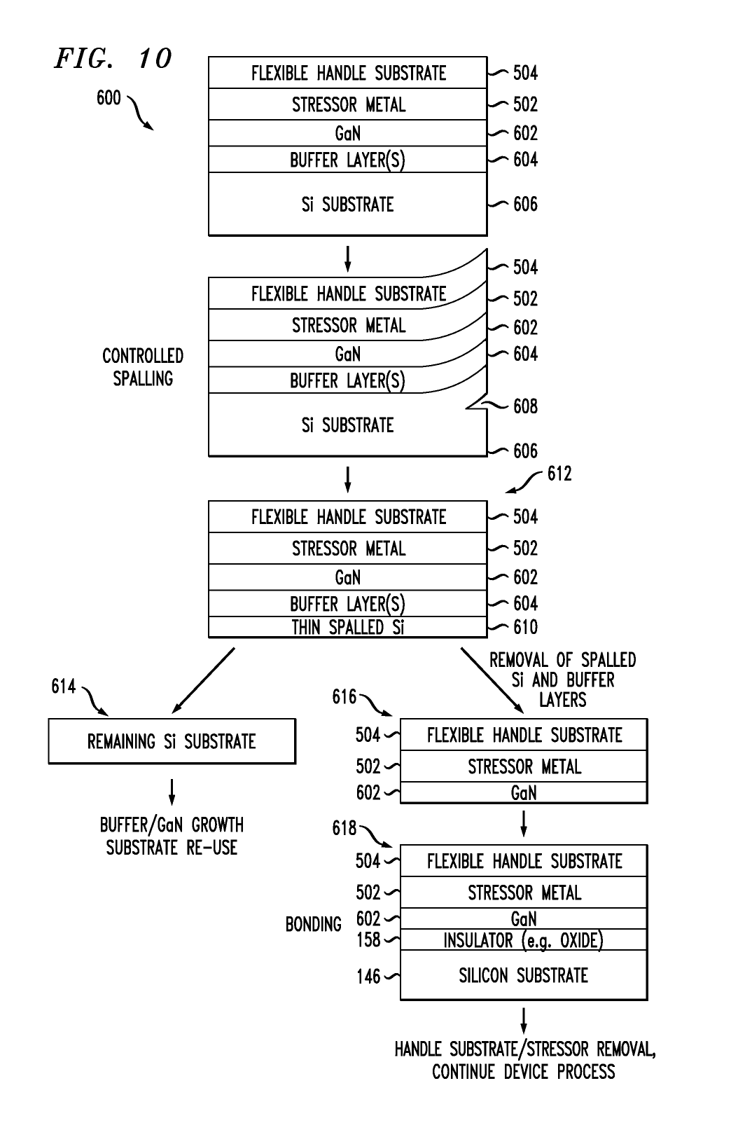

FIGS. 9 and 10 show schematic illustrations of exemplary processes that may be used entirely or in part to fabricate one or more of the HEMT or diode structures disclosed herein, it being appreciated that other processes could instead be employed. Referring to FIG. 9, a stressor metal layer 502 and a flexible handle substrate 504 are formed on an initial substrate 506. The initial substrate may comprise, for example, gallium nitride or gallium nitride on sapphire or silicon carbide. The flexible handle substrate 504 can be a flexible adhesive. The flexible handle substrate is used to cause tensile stress in the metal layer (e.g. nickel) to form a fracture 508 in the initial substrate 504. Two elements remain following this procedure, one 510 comprising the flexible handle substrate, the stressor metal layer 502 and a thin spalled gallium nitride layer 512, the other 514 comprising the remaining portion of the initial substrate 506. If the initial substrate is gallium nitride, it can be reused by forming another stressor metal layer on it followed by formation of a flexible handle substrate. If the initial substrate is gallium nitride on sapphire or silicon carbide, a gallium nitride layer can again be grown on the remaining portion of the initial substrate followed by deposition of the stressor metal layer and flexible handle substrate prior to reuse for the same procedure.

The element 510 including the thin spalled gallium nitride layer 512 is further processed to add, for example, an insulator layer 158 and a silicon substrate layer 146 such as those described with respect to the exemplary embodiment of FIG. 4. The flexible handle substrate 504 and stressor metal layer 502 are removed from this element 516 followed by further processing to form a superjunction layer if necessary and, using the example of FIG. 4, add the barrier layer, passivation layer, and electrodes.

FIG. 10 shows a process similar to that shown in FIG. 9, but starts with a different initial structure 600 and is preferred. The initial structure 600 includes a flexible handle substrate 504 and a stressor metal layer 502 formed on a gallium nitride layer 602. A buffer layer 604 is positioned between the gallium nitride layer 602 and a silicon substrate 606 (e.g. Si(111)). As discussed above, aluminum nitride may be employed as a buffer layer. A fracture 608 is formed in the silicon substrate 606, resulting in a first structure 612 including a thin spalled silicon layer 610 and the other layers 502, 504, 602, 604 discussed above and the remaining portion 614 of the silicon substrate 606. The spalled silicon and buffer layers 604, 610 can be removed to form a third structure 616 including the gallium nitride layer, stressor metal layer and flexible handle substrate. The third structure 616 can be bonded to the oxide layer 158 to form a fourth structure 618 similar to the structure 516 shown in FIG. 9. The flexible handle substrate and stressor metal layer can be removed followed by further processing to obtain, for example, the structure shown in FIG. 4. The superjunction can be formed either before or after spalling. It is also possible to form the superjunction, grow the barrier layer, and then conduct the spalling procedure. The principles of the techniques shown in FIGS. 9 and 10 can be applied to the fabrication of the Schottky diode structures discussed above with respect to FIGS. 5-8.

Given the discussion thus far, it will be appreciated that, in general terms, an exemplary high electron mobility transistor structure is provided that includes a doped gallium nitride superjunction layer 44 or 144 having a plurality of p/n junctions. A barrier layer adjoins the doped gallium nitride superjunction layer, the doped gallium nitride superjunction layer being positioned between a substrate layer 46 or 146 and the barrier layer 42 or 142. A two dimensional electron gas channel is formed in the doped gallium nitride superjunction layer near the junction of the doped gallium nitride superjunction layer and the barrier layer when a voltage is applied across the gate and source terminals. Low-resistivity contacts between source/drain and the channel material (GaN) may be achieved by various techniques used for conventional GaN HEMT devices as known in the art (not shown in the figures). Examples include but are not limited to opening contact vias in the AlGaN barrier layer, doping the AlGaN barrier layer with Al, forming metal-semiconductor alloys using thermal treatment, and combinations thereof; at/underneath source and drain terminal regions. A passivation layer overlies the barrier layer. In operation, an electric field set up by the doped gallium nitride superjunction layer upon application of a voltage to the gate electrode is vertical to an electric field set up between the gate electrode and the drain electrode. Breakdown at least between the gate and drain is suppressed. If the structure is a GaN-on-Si device, breakdown through the substrate layer is also suppressed.

It will further be appreciated that an exemplary high electron mobility transistor structure is provided that includes a doped gallium nitride superjunction layer having a thickness of less than ten microns and comprising a plurality of p/n junctions, the entirety of the thickness of the doped gallium nitride superjunction layer comprising a superjunction structure such as shown in FIGS. 2 and 4. An aluminum gallium nitride barrier layer adjoins the doped gallium nitride superjunction layer, the doped gallium nitride superjunction layer being positioned between a silicon substrate layer and the barrier layer. A two dimensional electron gas channel is formed in the doped gallium nitride superjunction layer near the junction of the doped gallium nitride superjunction layer and the barrier layer when a voltage is applied across the gate and source terminals, The doped gallium nitride superjunction layer is operable to suppress breakdown both through the silicon substrate layer and between the gate and drain. Improved device breakdown voltage is accordingly provided by this HEMT structure. The gate and drain electrodes in the above-referenced high electron mobility transistor structures can be electrically connected so that the structures function as diodes.

Schottky diodes are provided in accordance with further exemplary embodiments such as those shown in FIGS. 5-8. An exemplary Schottky diode structure includes a Schottky contact 250, 250′, a substrate 206, 246 having a top surface 206′, 246′, and a doped gallium nitride superjunction layer 204, 244 between the Schottky contact and the top surface of the substrate. The doped gallium nitride superjunction layer has a thickness of less than ten microns and comprises a plurality of p/n junctions (e.g. 244′). The entirety of the thickness of the doped gallium nitride superjunction layer 204, 244 comprises a superjunction structure. The p/n junctions extending vertically with respect to the top surface of the substrate as illustrated in FIGS. 5 and 6. As shown in FIG. 6, an insulating layer 258 may be provided between the substrate and superjunction layers.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A high electron mobility transistor structure comprising:
a doped gallium nitride superjunction layer comprising a plurality of p/n junctions;
a substrate layer;
a barrier layer adjoining the doped gallium nitride superjunction layer, the doped gallium nitride superjunction layer being positioned between the substrate layer and the barrier layer;
a source electrode;
a drain electrode;
a gate electrode, and
a passivation layer overlying the barrier layer,
wherein an electric field set up by the doped gallium nitride superjunction layer is vertical to an electric field set up between the gate electrode and the drain electrode upon application of a voltage to the gate electrode.

2. The high electron mobility transistor structure of claim 1, wherein the barrier layer is comprised of aluminum gallium nitride.

3. The high electron mobility transistor structure of claim 2 further including a buffer layer comprised of aluminum nitride between the substrate layer and the doped gallium nitride superjunction layer.

4. The high electron mobility transistor structure of claim 2 further including a second layer of aluminum gallium nitride between the substrate layer and the doped gallium nitride superjunction layer, the second layer of aluminum gallium nitride adjoining the doped gallium nitride superjunction layer.

5. The high electron mobility transistor structure of claim 4 further including a buffer layer comprised of aluminum nitride between the substrate layer and the doped gallium nitride superjunction layer.

6. The high electron mobility transistor structure of claim 5 wherein the substrate is comprised of silicon(111).

7. The high electron mobility transistor structure of claim 1 wherein the substrate is comprised of silicon(111).

8. The high electron mobility transistor structure of claim 1 further including an insulating layer between the substrate layer and the gallium nitride superjunction layer.

9. The high electron mobility transistor structure of claim 8 wherein the insulating layer is a buried oxide layer.

10. The high electron mobility transistor structure of claim 8 wherein the substrate is comprised of silicon(111), further including an aluminum nitride buffer layer between the substrate layer and the doped gallium nitride superjunction layer.

11. The high electron mobility transistor structure of claim 1 wherein the doped gallium nitride superjunction layer has a thickness of less than ten microns, the entire thickness of the doped gallium nitride superconductor layer comprising a superjunction structure.

12. A high electron mobility transistor structure comprising:
a doped gallium nitride superjunction layer having a thickness of less than ten microns and comprising a plurality of p/n junctions, the entirety of the thickness of the doped gallium nitride superjunction layer comprising a superjunction structure;
a silicon substrate layer;
an aluminum gallium nitride barrier layer adjoining the doped gallium nitride superjunction layer, the doped gallium nitride superjunction layer being positioned between the substrate layer and the barrier layer;
a source electrode;
a drain electrode, and
a gate electrode, the doped gallium nitride superjunction layer being operable to suppress breakdown both through the silicon substrate layer and between the gate and drain electrodes.

13. The high electron mobility transistor structure of claim 12, further comprising an insulating layer between the substrate layer and the doped gallium nitride superjunction layer.

14. The high electron mobility transistor structure of claim 13, wherein the insulating layer is a buried oxide layer.

15. The high electron mobility transistor structure of claim 13, further including a buffer layer between the substrate layer and the doped gallium nitride superjunction layer.

16. The high electron mobility transistor structure of claim 15, wherein the buffer layer is comprised of aluminum nitride.

17. The high electron mobility transistor structure of claim 12, further including a second aluminum gallium nitride barrier layer adjoining the doped gallium nitride superjunction layer.

18. The high electron mobility transistor structure of claim 12, wherein the substrate is a silicon-on-insulator substrate.

19. The high electron mobility transistor structure of claim 12, further including a buffer layer between the substrate layer and the doped gallium nitride superjunction layer, the substrate layer being comprised of silicon (111).

20. The high electron mobility transistor structure of claim 12, wherein the doped gallium nitride superjunction layer, the barrier layer, the substrate layer, and the gate, drain and source electrodes are operable to form a conductive, two dimensional electron gas channel within the doped gallium nitride superjunction layer near the barrier layer and cause an electric field set up by the doped gallium nitride superjunction layer to be vertical to an electric field set up between the gate and drain electrodes and also vertical to an electric field set up between the drain electrode and the substrate layer.

21. A Schottky diode structure comprising:
a Schottky contact;
a substrate having a top surface, and
a doped gallium nitride superjunction layer between the Schottky contact and the top surface of the substrate, the doped gallium nitride superjunction layer having a thickness of less than ten microns and comprising a plurality of p/n junctions, the entirety of the thickness of the doped gallium nitride superjunction layer comprising a superjunction structure, the p/n junctions extending vertically with respect to the top surface of the substrate.

22. The Schottky diode structure of claim 21, further comprising a passivation layer on the doped gallium nitride superjunction layer.

23. The Schottky diode structure of claim 22, wherein the substrate comprises Si(111).

24. The Schottky diode structure of claim 23, further including an insulating layer between the substrate and the doped gallium nitride superjunction layer.

25. The Schottky diode structure of claim 23, further comprising one of an AlGaN or GaN/AlN superlattice layer between the substrate and the doped gallium nitride superjunction layer.
